(19) United States
(12) Patent Application Publication
(10) Pub. No.: US 2019/0281238 A1
(43) Pub. Date: Sep. 12, 2019

(54) DOUBLE SOURCE FOLLOWER HDR PIXEL

(71) Applicant: Caeleste CVBA, Mechelen (BE)

(72) Inventor: Ajit Kumar KALGI, Antwerpen (BE)

(21) Appl. No.: 15/916,685

(22) Filed: Mar. 9, 2018

(51) Int. Cl. H04N 5/355; H01L 27/146

(52) U.S. Cl. CPC H04N 5/3559; H01L 27/14643; H04N 5/35572; H04N 5/35509; H01L 27/14612

(57) ABSTRACT

A pixel structure comprises at least one radiation-sensing element, for generating charges when exposed to radiation. The pixel structure includes a first connection arrangement between the at least one radiation-sensing element and a first source follower. The first connection arrangement has a switchable connection to a first reset voltage. At least one second connection arrangement is between the at least one radiation-sensing element and at least one second source follower. The second connection arrangement has a switchable connection to a second reset voltage. The first and at least one second source followers have a common output. The first and second connection arrangements and source followers are configured to provide each a different offset to the common output.

### FIELD OF THE INVENTION

The present invention relates to the field of image sensors. More specifically it relates to pixel circuits for image sensors comprising photodiodes.

### BACKGROUND OF THE INVENTION

Image sensors, radiation sensors, and related technology usually include photoelectric elements, such as photodiodes, as light-sensitive elements which give a measurable response (photocharges) when radiation impinges upon them. These elements usually comprise a surface provided on or in a substrate. When radiation impinges on the sensitive element, charges are generated, accumulated in the element and transferred to a capacitor node (usually a floating diffusion node) through a transfer gate. Charges are collected for readout from the capacitor node by connecting that node to a gate of a transistor. The actual readout is done by reading the corresponding current. Usually, the photosensitive element and the circuit elements that collect the charges therein for readout altogether are called a “pixel”. A sensor typically comprises an array of pixels laid out next to one another, together with wiring, connections and readout circuits and drivers. At present, a standard image sensor presents some or all of these elements integrated in a substrate, usually a semiconductor substrate.

However, photoelectric elements have a limited storage capacity. The full well capacity is one of the limits of the dynamic range of the image sensor. Several issues are linked to the limit of capacity, for example the speed of transfer, overflow of charges, which may affect adjacent or nearby pixels, etc. Moreover, as practically all sensor and electronics technology tends to evolve towards miniaturization and high integration, the problem worsens as the sizes decrease. Most commercial applications already require highly integrated sensors, which requires miniaturization. Decreasing the physical size of the pixel and of the sensing element leads to higher risks of overflow, reduced full well capacity, etc. Different solutions with different degrees of complexity have been devised, such as use of more than one transfer gate with different layouts, or use of avalanche photodiodes.

For example, US2012/002089 shows a pinned photodiode (PPD) with two transfer gates, one at each side of the surface of the photodiode, which allow charge flow to respective floating diffusion nodes. One of the gates allowing the transfer can be biased at three levels, allowing charge to overflow to the corresponding floating diffusion node, thus extending dynamic range of operation. For example, the floating diffusion node can be used to store overflow charges from the pinned photodiode or from the other floating diffusion node. The sensitivity and dynamic range may increase in such way.

There is a need to readout all the charges from a photodiode at all illumination levels. Hence both high sensitivity and high dynamic range are required. However, transfer and readout speed are not always good or optimal, especially for high sensitivity sensors.

### SUMMARY OF THE INVENTION

It is an object of embodiments of the present invention to provide a pixel structure and a method for reading out a sensing element, presenting high readout speed for a wide range of illumination levels, and high dynamic range.

In a first aspect, the present invention provides a pixel structure comprising at least one radiation-sensing element, for generating charges when exposed to radiation. The pixel structure comprises

a first connection arrangement between the at least one radiation-sensing element and a first source follower, the first connection arrangement comprising a switchable connection to a first reset voltage,

at least one second connection arrangement between the at least one radiation-sensing element and at least one second source follower, the second connection arrangement comprising a switchable connection to a second reset voltage.

The first and at least one second source followers have a common output. The first and second connection arrangements and source followers are configured to provide each a different offset to the common output.

It is an advantage of embodiments of the present invention that a non-linear response of the pixel structure can be obtained, the small signal contribution to the response being read through one of the source followers, the large signal contribution through the other source follower. It is a further advantage that the pixel undergoes a “reset” readout and a “signal” readout only. In particular embodiments of the present invention, the higher and lower sensitivity ranges can be altered for instance by changing the first and second reset voltage levels.

In a pixel structure according to embodiments of the present invention, the first and at least one second connection arrangements may present different sensitivity.

In a pixel structure according to embodiments of the present invention, the first and at least one second source followers may comprise transistors having different threshold voltages.

In a pixel structure according to embodiments of the present invention, each of the first and at least one second connection arrangements may comprise a connection to a first and at least one second power supply, respectively, for resetting a starting voltage of the first and at least one second source follower via respective switches, wherein the first and at least one second power supplies provide different voltages to the respective connection arrangements.

It is an advantage of embodiments of the present invention that the reset voltage can be tailored and tuned by changing the voltage of a suitable source connected to the drain of one of the reset transistors.

In a pixel structure according to embodiments of the present invention, the first connection arrangement and second connection arrangements each comprise a floating diffusion node and a transfer gate, the transfer gate being for transferring charges from an associated radiation-sensing element to the floating diffusion node of that connection arrangement, wherein each connection arrangement is configured to provide a different voltage at its floating diffusion node under a same amount of charges on the associated radiation-sensing element. The transfer gate of at least one of the first or second connection arrangements may be a multi-level transfer gate adapted to be biased to a first bias voltage for allowing passage of charges to the floating diffusion, a second bias voltage for stopping flow of charges and to an intermediate bias voltage for allowing passage of overflown charges to the floating diffusion.

It is an advantage of embodiments of the present invention that global shutter can be obtained in a pixel array comprising pixel structures according to the present invention. It is an advantage of embodiments of the present invention that the multi-level transfer gate enables a pixel with overflow control, anti-blooming capacities and compact design.

A pixel structure according to embodiments of the present invention may further comprise a merge switch between the floating diffusion node of the first connection arrangement, and the floating diffusion node of one of the second connection arrangements. It is an advantage of embodiments of the present invention that the pixel has more flexibility, and for example the functionality of the circuit can be activated or turned off.

In a pixel structure according to embodiments of the present invention, at least one of the connection arrangements between the at least one sensing element and one of the first and second source followers may further comprise an external capacitor. The value of the capacitor should be such that the gain of the path with capacitor is lower than the gain of the path without capacitor. The value can be large enough to store all the charges from the radiation-sensing element.

It is an advantage of embodiments of the present invention that charge storage can be increased, for example the floating diffusion may store higher levels of charge.

In a pixel structure according to embodiments of the present invention, the common output of the source followers is connectable to a column output via a select switch.

It is an advantage of embodiments of the present invention that the pixel structure can be implemented in a standard pixel structure.

In a pixel structure according to embodiments of the present invention, the at least one light-sensing element is a single light-sensing element.

It is an advantage of embodiments of the present invention that the pixel structure can be made compact.

In a pixel structure according to embodiments of the present invention, the at least one light-sensing element may comprise a plurality of light-sensing elements, the first and at least one second connection arrangements each connecting one of the plurality of sensing elements to a respective one of the first and at least one second source followers.

It is an advantage of embodiments of the present invention that the pixel design can be more flexible, and different sensitivity can be easily introduced in each sub-pixel.

In a pixel structure according to embodiments of the present invention, the plurality of light-sensing elements may comprise any combination of PDs, PPDs, APDs, or SPADs.

In a second aspect, the present invention provides a method for reading out at least one radiation-sensing element, the method comprising:

integrating electric charges generated by the at least one radiation-sensing element as a response to impinging radiation,

transferring generated charges from the at least one radiation-sensing element to a first source follower via a first connection arrangement comprising said first source follower,

transferring (or overflowing) generated charges from the at least one radiation-sensing element to a least one second source follower via at least one second connection arrangement comprising said at least one second source follower,

wherein the first and at least one second connection arrangements and source followers are configured to provide each a different offset to a common output, and

reading, by means of the first and second source followers, via the common output, an output value indicative of the amount of transferred charges.

In a method according to embodiments of the present invention, transferring generated charges to the first and at least one second source follower may be done sequentially or simultaneously.

It is an advantage of embodiments of the present invention that reading requires only reset level readout and signal level readout after the charge transfer, thus enabling high speed applications.

In a method according to embodiments of the present invention, transferring generated charges may comprise:

transferring generated charges to a storage node in electric contact with the first source follower via a first transfer gate, the first transfer gate being adapted to transfer charges to a floating diffusion node connected to an input of the first source follower,

transferring generated charges to at least a second storage node in electric contact with the least one second source follower via at least one second transfer gate, the at least one second transfer gate being adapted to transfer charges to at least one second floating diffusion node connected to an input of the second source follower,

wherein the first and at least one second floating diffusion nodes present a different voltage at reset level.

It is an advantage of embodiments of the present invention that charge transfer can be made at high speed and the source followers may have the same physical characteristics.

It is an advantage of embodiments of the present invention that after simultaneous or sequential charge transfer to the floating diffusions in the pixel structure, the signal level on the common output of one or more source followers is proportional to the charges generated on the radiation sensitive element.

In a method according to embodiments of the present invention, the first and at least one second source followers may comprise different threshold voltages for providing different offset.

It is an advantage of embodiments of the present invention that charge reading can be fast, and only reset and reading stages are needed.

Particular and preferred aspects of the invention are set out in the accompanying independent and dependent claims. Features from the dependent claims may be combined with features of the independent claims and with features of other dependent claims as appropriate and not merely as explicitly set out in the claims.

These and other aspects of the invention will be apparent from and elucidated with reference to the embodiment(s) described hereinafter.

### BRIEF DESCRIPTION OF THE DRAWINGS

FIG. 1 illustrates a general embodiment of the present invention, for a general case with two sub-pixels and for a general case with source followers with different threshold values.

FIG. 2 illustrates a particular embodiment with a single PPD and two different reset voltages.

FIG. 3 illustrates a particular embodiment with a single PPD and one source follower having a lower threshold voltage than the other one.

FIG. 4 illustrates two alternatives for an embodiment of the present invention, including a larger drain-source bias across the transfer gate or additional series transistor to allow charge multiplication.

FIG. 5 illustrates a particular embodiment of the present invention, comprising signal paths with different capacitance.

FIG. 6 illustrates a particular embodiment of the present invention, comprising charge multiplication.

FIG. 7 illustrates a particular embodiment of the present invention, comprising two photodiodes of different size.

FIG. 8 illustrates a particular embodiment of the present invention, comprising a PPD and an APD or SPAD.

FIG. 9 shows a diagram of the voltage at the readout column showing high sensitive range and low sensitive range as a function of the incident radiation.

The drawings are only schematic and are non-limiting. In the drawings, the size of some of the elements may be exaggerated and not drawn on scale for illustrative purposes.

Any reference signs in the claims shall not be construed as limiting the scope.

In the different drawings, the same reference signs refer to the same or analogous elements.

### DETAILED DESCRIPTION OF ILLUSTRATIVE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

The terms first, second and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

In the description provided herein, numerous specific details are set forth. However, it is understood that embodiments of the invention may be practiced without these specific details. In other instances, well-known methods, structures and techniques have not been shown in detail in order not to obscure an understanding of this description.

Where in embodiments of the present invention reference is made to “pixel”, reference is made to a structure comprising at least one photoreceptor (or sensing element) and a circuit for collecting charges generated in the at least one photoreceptor for readout. Usually, one or more elements of the pixel are integrated on or in the surface of a substrate, usually a semiconductor surface. Sensing elements are usually photoelectric elements.

The present invention relates to a pixel structure and included circuit which converts radiation induced charges of sensing elements into a signal that can be read at an output, through a signal path. Where in embodiments of the present invention reference is made to “signal path”, reference is made to a route that a signal may follow, including connections, conductive paths, etc. from the element of the circuit where charges are generated to the output where a signal based on the generated charges can be read. A signal path may be connected to a radiation-sensitive element where charges are generated. The signal path includes a connection arrangement including a reset stage (for example, a switch or transistor for allowing connection to a voltage source) and an amplification stage. Two signal paths may include each a connection arrangement including a reset stage and an amplification stage, both signal paths being connected to two separate radiation-sensitive elements, or to a single radiation-sensitive element, e.g. connected in different zones of the element. The connection arrangements may include further elements, such as floating diffusion (FD) nodes, quenching stages, etc.

Where in embodiments of the present invention reference is made to “reset level” or “reset voltage” (or RST level), reference is made to the voltage on the floating diffusion node at beginning of integration time (before receiving radiation). A switch for providing a reset voltage to the floating diffusion node is called a reset switch RST.

Where in embodiments of the present invention reference is made to “offset level”, reference is made to the voltage level on all the floating diffusions of the signal paths before the beginning of integration, e.g. before charges are generated and collected in the sensing element.

Some radiation sensing elements, such as photoelectric elements (e.g. photodiodes), generate charges as a response to impinging radiation. The amount of charges that a sensing element can generate is determined by the amount of radiation impinging on the element and by the response of the element to radiation. For example, a photoelectric element with low photo-response generates less charges than a photoelectric element with higher photo-response, for a same amount of light. This may be due to difference of sensing areas, different materials showing different photo-responsivity, etc.

The generated charges are transferred to one or more charge storage nodes, for example FD nodes, etc. in order to make them readable (for example through the input of a transistor, operational amplifier, or other readout means). A starting voltage can be applied to the charge storage nodes by means of a “reset transistor” or RST switch. In particular, the charges in a FD node can be used as input of an amplification stage, such as a source follower, for readout. In conditions of high radiation intensity, a high amount of charge is generated, which can polarize strongly the gate of the source follower transistor and the corresponding current signal through that transistor will be high. These charges, when transferred onto floating diffusion, cause a large voltage drop at the output. In low illumination conditions, the charge levels will be lower, hence lower voltage drop at the output after charge transfer.

The charges generated in one or more radiation sensitive elements can be read out through a single output. In a theoretical case, it is possible to use a plurality of signal paths, each path including a source follower with their outputs shunted. The output would be taken over by the source follower with the highest voltage at the input. The signal would be read through this path. As the charges are being transferred, the voltage of all paths change equally and simultaneously, so the signal would always be read through the same output.

The present invention provides a pixel structure, for a radiation sensor, including a plurality of signal paths, one of which presents a higher offset voltage than the others. Thus, the path with the highest offset (e.g. highest input voltage at reset level) dominates at start of integration. However, unlike in the theoretical case, as the radiation levels increase, the charges are transferred and the signal through the path with highest sensitivity drops faster than the signals through the other paths. Thus, the path presenting lower sensitivity will dominate as the amount of charge increases over a threshold that can be predetermined.

This provides a dynamic sensitivity and high speed readout, in which the readout is faster due to combined readout of high sensitivity and low sensitivity signal paths while the sensitivity is dynamically adjusted due to shunted source follower readout.

In a first aspect, the present invention relates to a pixel structure which optimizes charge reading, by providing high sensitive reading of charges generated at low illumination conditions, while at the same time providing low sensitive reading of charges generated at high illumination conditions. Additionally the pixel output under low illumination can be subtracted with its reset level to cancel the sampled noise on floating diffusion. The pixel structure of the present invention presents a non-linear response. The pixel structure is adapted to read a small signal, for example at start of integration, via high-sensitivity sub-pixel, and a large signal, for example in high illumination conditions after a period of integration, via a low sensitivity sub-pixel.

Embodiments of the present invention provide a pixel structure with at least two different signal paths for reading charges generated under high illumination and under low illumination conditions. The pixel structure of the present invention provides “pulling” the charge obtained in low radiation intensity conditions to a first voltage applied to the input of a first amplification stage, and in high radiation intensity conditions, to at least a second voltage, lower than the first voltage, applied to the input of a second amplification stage, both stages sharing a same output. Thus when the intensity of illumination is high, the dominant readout is pulled to a lower voltage level, and the readout of the path with reduced sensitivity will dominate. The readout is performed at the output of the amplification stages, via either the path with reduced sensitivity and high readout speed due to single readout, or the path with high sensitivity when illumination is low.

In embodiments of the present invention, the pixel structure may comprise one or more sensing elements. The sensing element can be a photoelectric conversion unit, for example a photodiode, particularly a pinned photodiode, for example comprising a p+ pinning layer and n pinned layer. However, more than one sensing element can be used, which may be of a same kind but do not need to. Not only photodiodes can be used, and types of sensing elements such as avalanche diodes can be used, or combinations of different types of sensing elements. Two sub-pixels may comprise a same sensing element, connected to a single output via different connection arrangements.

In embodiments of the present invention, the pixel structure is adapted and driven such that the path with the highest sensitivity, specifically highest radiation response (for example highest photo-response), presents the highest offset. The sensitivity can be defined as

S=dV/dP

wherein P is a magnitude related to e.g. radiation power, light flux, particle flux, etc., and V is the voltage at the start of integration.

The path that the signal follows to the output is, at the beginning of the readout operation, determined by the offset at the start of integration. However, the path is not fixed during the whole readout, and it may change by the amount of charges transferred from the sensing element.

This effect can be obtained by adapting the signal paths in a suitable way. Some examples are given:
providing different reset levels at different floating diffusion nodes.
providing different threshold voltages in different source followers.

Other ways of providing different voltages at reset levels, before integration, in each of the signal paths can be used.

In embodiments of the present invention, the amplification stages are two shunted source followers (SFs). The shunt provides a single output for both SFs. In the case of shunted SFs, the SF with the highest voltage at start of integration determines the voltage on the output. Upon transfer of charges from a photodiode, the voltage at the inputs of the SFs starts changing. At some point, the readout may be taken over by the other SF, which presents lower voltage at reset level on the floating diffusion, and a faster response. For example, the SF which provides highest sensitivity may be the SF connected to the floating diffusion node presenting the highest voltage at reset level, as is the case of two n-MOSFETs as SF, e.g. connected to a high reset voltage. The present invention is not limited to n-MOSFETs, and adapting the setup for using p-MOSFETs, for obtaining analogous response, is within the common knowledge of the field.

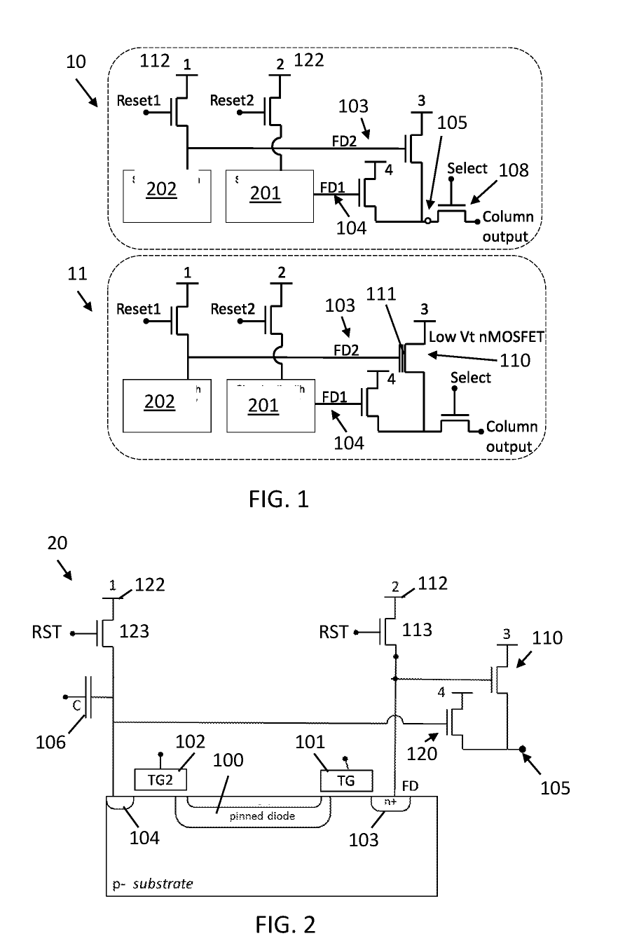

The topology of FIG. 1 shows two general implementations of a pixel according to embodiments of the present invention. FIGS. 2 to 8 can be seen as particular implementations of this general concept.

The pixel 10, 11 can be divided in two sub pixels, each comprising a signal path 201, 202 with different (low and high) sensitivities, and a common output. In some embodiments, the pixel 10, 11 has two or more source followers, each arranged for reading out charges, for example from a floating diffusion node 103, 104, or in general a node for temporarily storing charge. The first signal path 201 (with lower sensitivity of the two paths) comprises a first FD1 104 and a reset (RST) switch connected to a source providing a first reset voltage level 122. Analogously, the second signal path 202 (with higher sensitivity of the two paths) comprises a second charge storage node FD2 103 and a reset switch connected to a source providing a second predetermined reset voltage 112, which may be the same or different source as the source of the first path. Each signal path comprises a source follower. Sub pixels may have separate photoreceptors or share a common photoreceptor. For instance, the signals may be obtained from a single photodiode, or from two photodiodes, physically or optically separated from each other, in the same pixel. The output of both paths is a common output 105. For example, the two source followers may have a common, shunted, output. The common output may be connected to a select switch 108 for a column output.

In the embodiment shown in the upper scheme, the predetermined reset voltage level 112 of the second path (high sensitivity path) 202 is higher than the reset voltage level 122 of the first path 201. In this case, the sensitivity is determined by the reset voltages. The floating diffusion nodes 103, 104 are reset to the levels determined by the respective levels 112, 122 determined by corresponding reset voltage sources. For example, they may be different voltage sources. In this case, the source followers in each path may present the same characteristics (e.g. they may be source followers with same transistor characteristics). In the case of the lower scheme in FIG. 1, the sensitivity of the output is determined by the voltage threshold of the source followers. The transistor of the source follower 110 of the high sensitive path has a lower threshold voltage than the second source follower in the low sensitive path, providing the required different offset. In this case, a single voltage source can be used for the reset transistors, so the same reset voltage can be applied to both paths.

The pixel is adapted so that the charges generated by light impinging on the pixel will be read through the common output 105. At low radiation levels, or at the beginning of the integration time, the highest sensitivity sub pixel will dominate the general pixel output. In embodiments of the present invention, the shunted source followers follow the floating diffusion with highest reset voltage.

Then at a predetermined radiation level, the signal of the high sensitivity sub pixel drops faster than the other subpixel or subpixels, and reaches the level of the low sensitivity sub pixel(s). At a radiation level higher than this predetermined level, the low sensitivity subpixel will dominate the overall pixel's output.

In case of source followers using NMOSFET, the source of shunted source followers follows the gate voltage biased at a highest bias voltage. The pixel structure according to embodiments of the present invention is constructed and driven such that the highest sensitivity sub pixel (i.e. the sub pixel for which dV/dP is the highest, with dV representing the change in generated voltage, based on a change dP in received radiation power, light flux, particle flux etc.) has the highest voltage on its floating diffusion node at reset level, i.e. at the beginning of the integration time or before receiving light or particles.

For example, in case of low radiation conditions, the highest sensitivity sub pixel will dominate the general pixel output, because the pixel structure is constructed and driven such that its reset voltage is higher, as stated above. Yet at a predetermined radiation level, the signal of the high sensitivity sub pixel has dropped faster than the other(s) and reaches the level of the low sensitivity sub pixel. Beyond that radiation level, the path of the low sensitivity sub pixel dominates the pixel output. The signal on both SFs are thus read out simultaneously by shunting the source of the SF on the column bus, and the output will be dominated by one path or the other, depending on the illumination conditions.

In a particular embodiment, illustrated in FIG. 2, a pixel structure 20 comprising a single sensing element 100 and two signal paths are provided. The sensing element 100 (e.g. a single PPD) is connected, via two transfer gates 101, 102, to respective floating diffusion nodes 103, 104. Each floating diffusion nodes 103, 104 is connected to a respective amplifier, both connected to a common output 105. In embodiments of the present invention, each amplifier comprises a source follower (SF) 110, 120, and the floating diffusion nodes 103, 104 are connected to the respective gate of source followers 110, 120. Further, two reset switches 113, 123, which may be transistors, are provided for controlling the reset level of the floating diffusion nodes 103, 104. One or more capacitors 106 can also be used to increase the amount of charge that can be accumulated in the floating diffusion nodes 103, 104. In embodiments of the present invention, the pixel circuit is adapted to provide amplification with different gain in each amplifier 110, 120. In the embodiment of FIG. 2, each reset switch 113, 123 is biased to different bias voltages 112, 122 (provided by two sources, or by a single source providing different voltages to two different lines). The floating diffusion nodes 103, 104 are thus subjected to different reset voltage levels, thus obtaining different gain in the source followers 110, 120. The gain of each source follower can be advantageously tuned by conveniently adapting the reset voltage level. The high sensitive path will be determined by the floating diffusion (103 or 104) connected to the highest reset level bias voltage (112 or 122). For example, in some embodiments of the present invention, the leftmost reset switch 123 may be biased to the highest voltage 122, so the high sensitive path which will take over the readout will be the one formed by the left-hand floating diffusion 104 connected to the gate of the corresponding source follower 120. Optionally, capacitor 106 increases the charge acceptable by the floating diffusion 104. It can also accept charges during integration, if the transfer gate 102 can be biased to an intermediate level during integration, hence allowing charge overflown to the capacitor. The capacitor affects the sensitivity of the path.

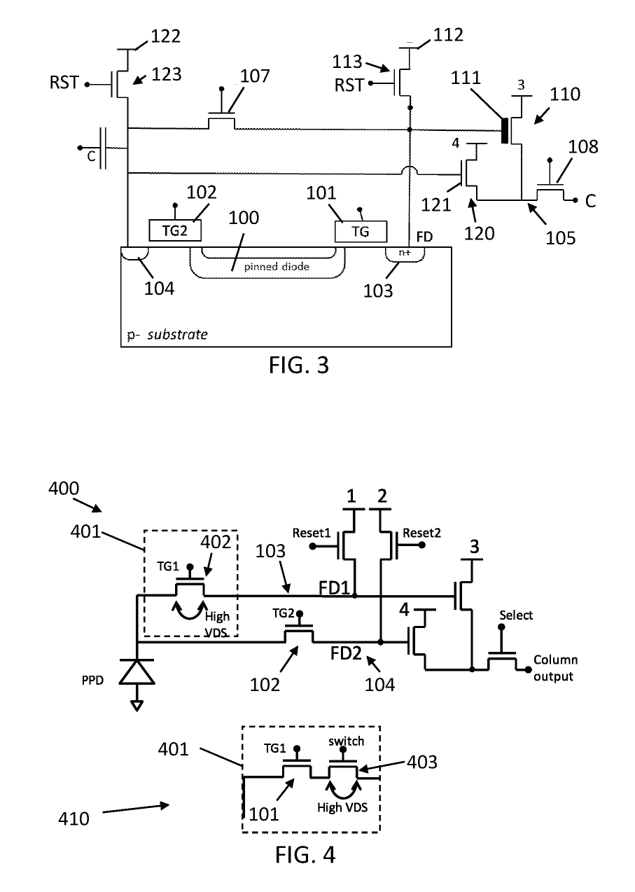

FIG. 3 shows a configuration similar to FIG. 2, with optional and additional features, which may also be implemented in other embodiments of the present invention. An optional merge switch 107 can be included, which can be used to merge charges and/or activate and de-activate the functionality of providing a sensitive readout of a low level of charges and a high speed readout of a high level of charges. Further, a select switch 108 is shown for controlling the connection between the common output 105 and for example a column output. The merge switch 107 and the select switch 108 are independent features, which may be used in a pixel structure in accordance with embodiments of the present invention, in isolation or in combination with one another. Other optional features can also be implemented. For example, one of the transfer gates (for example, the transfer gate 102 connected to the high sensitive path) may be a three-level transfer gate, allowing overflow management for example, by introducing an intermediate voltage, for example by biasing the transfer gate to an intermediate voltage during charge integration. The excess charges generated in the photodiode 100 (e.g. a PPD) due to incident radiation during the integration time overflows the transfer gate 102 (biased e.g. at a DC voltage) into the corresponding floating diffusion 104. The remaining charges in the photodiode 100 can be transferred after the integration time into the corresponding floating diffusion 103 by toggling its transfer gate 101. Thus, overflown charges may leave the photodiode 100 in a controlled way, optionally also accumulating such charges in a capacitor 106, e.g. an external capacitor or similar. These features can be applied to other embodiments of the present invention, not only to the one shown in FIG. 3.

In the particular embodiment of FIG. 3, the two gates 111, 121 of the source followers 110, 120 are shown with different symbols, signifying that the respective source followers 110, 120 present significantly different threshold voltage (Vth). “Significantly different” means in this context that the difference of threshold voltage should be provided by design, and not incidentally different due to for example variations of manufacture. The source follower 110 in the high sensitivity signal path is denoted with a thicker line at the gate 111, representing that its threshold voltage is lower. The difference is controlled and tailored, so a predetermined difference of threshold voltage Vth is obtained, thus providing different signal paths according to the signal sent to each particular floating node. For example, the threshold voltages Vth may have a value of 0.3 V and 0.7 V. The source follower with 0.3V is used in a signal path with high sensitivity while the source follower with 0.7V is used for a signal path with low sensitivity. The resulting voltage range for high sensitivity is (0.7−0.3=0.4 V). Specifically, the signal path for the signal obtained under high sensitivity conditions should comprise source follower with lowest threshold voltage Vth of the two.

In case the source followers are adapted to present a predetermined difference of threshold voltage Vth, it is not necessary to provide two different reset voltage levels 112, 122, so both rest switches 113, 123 can be connected to the same voltage level provided by the same power source, advantageously reducing electric components and sources.

The reset switches 113, 123 may also be used to control shutter, for example providing global shutter functionality. Reset switch 123 in the high-sensitivity signal path, connected to the optional three-level transfer gate 102, can be a shutter switch for controlling global shutter option, for instance.

In the following description, several examples and embodiments of pixel structures according to the present invention are illustrated, such as the ones of FIGS. 4 to 8. In each embodiment, the high sensitivity path and the low sensitivity path have a different offset. This different offset may be obtained in any suitable way, such as for instance by having different reset voltages, or different threshold at the source followers, etc.

FIG. 4 shows an upper drawing 400 with a single sensing element, e.g. photodiode PPD, connected to the two paths, with or without charge multiplication. In this case, the single sensing element PPD is connected to the floating diffusion 103 in the high-sensitivity path through a transfer means 401. The voltage drop at the floating diffusion 103 in the high-sensitivity path is larger than at the other floating diffusion 104 in the low-sensitivity path. In a particular embodiment, the transfer means 401 is a MOSFET or transfer gate 402 provided with a high drain-source (VDS) voltage. In an alternative embodiment for transfer means, shown in the lower drawing 410, the transfer means 401 comprises a first transfer gate (e.g. a transistor, e.g. MOSFET) 101 and a second transistor (e.g. MOSFET) 403 provided with a high VDS voltage. The high VDS causes electron multiplication, also known as hot carrier multiplication, and thus the voltage change at the first floating diffusion 103 is larger than the voltage change at the second floating diffusion 104.

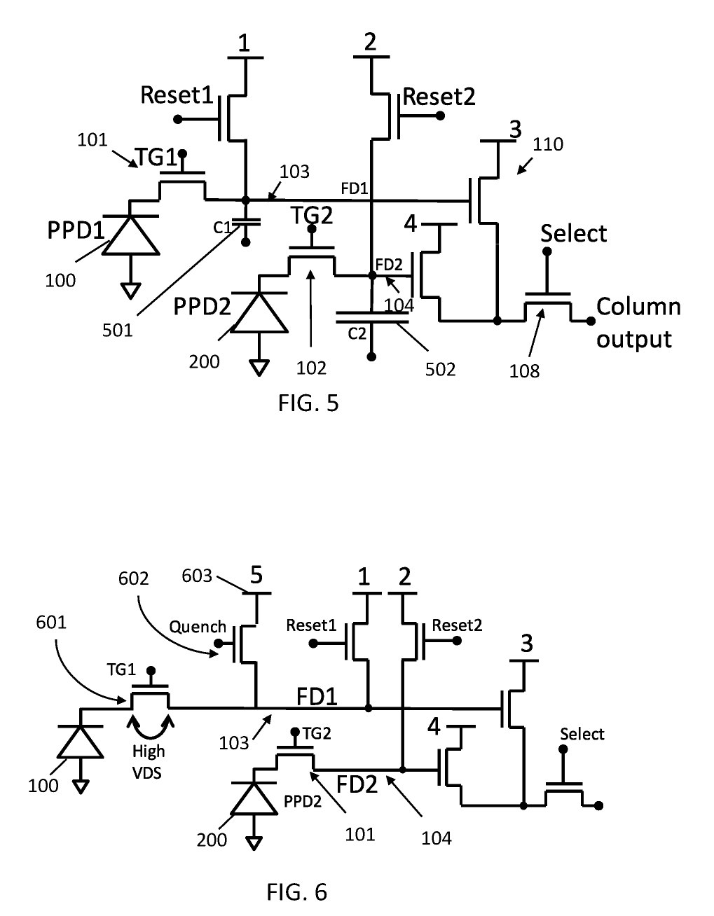

Embodiments of the present invention may also comprise separate sensing elements, e.g. photoreceptors, rather than a single one. In the particular embodiment illustrated in FIG. 5, two sub pixels are shown, each having a separate photodiode 100, 200. Both photodiodes 100, 200 may have the same size and sensitivity. The arrangement allows the integrated charge on the first photodiode 100 to be transferred, through a first transfer gate 101, to a first storage node (such as a first capacitor 501) with relatively small capacitance, for higher charge-to-voltage conversion. In turn, the integrated charge on the second element 200 can be transferred to a second storage node (e.g. comprising a second capacitor 502), also for charge to voltage conversion, through a second transfer gate 102.

The sensitivity of each floating diffusion node can be defined with respect to the charge, dV/dQ. This value can be tailored and controlled by adding capacitors with different capacitance, to ensure that one path presents higher sensitivity. The total capacitance of the floating diffusion 104 of the signal path with lower sensitivity can be tailored to be higher than the total capacitance of the floating diffusion 103 of the path with high sensitivity.

Specifically in FIG. 5, the second node (the floating diffusion including e.g. the second capacitor 502) presents a relatively high capacitance, significantly higher than the capacitance of the first node (the floating diffusion including e.g. the first capacitor 501).

In this case, the high sensitivity path is given by the path comprising the lowest capacitance (the photodiode 100 and the transfer gate 101 connecting it to respective capacitor 501, floating diffusion 103 and source follower 110). The sensitivity is higher due to the larger charge-to-voltage conversion factor from the smaller capacitance, according to the equation C=Q/V. In other words, the source follower providing high sensitive reading is the source follower 110 with the gate connected to the storage node 103 with small capacitance 501, and the output of that source follower takes over, being sent to the column output through the select switch 108.

Other means to provide higher sensitivity, providing higher input in one source follower than in other source follower(s), may include for example electron multiplication means. FIG. 6 shows a pixel topology with a sub-pixel comprising a first sensing element, e.g. PPD 200, and another sub-pixel comprising a second sensing element, e.g. PPD 100. The setup is similar to the first alternative of FIG. 4, but with two sensing elements rather than a single one. Furthermore, in this embodiment, the transfer means is adapted to work under avalanche conditions. Thus, the setup has functionality similar to an APD. For example, a photodiode 100 is connected to a floating diffusion node 103 through a first transfer gate TG1 601 (e.g. a MOSFET) and provided with a sufficiently high drain source (VDS) voltage. The high VDS ensures that there is electron multiplication. The voltage drop at the node 103 connected to such high VDS gate 601 is larger than voltage drop with a low VDS of a typical transistor. Accordingly, the second sensing element PPD 200 connected to the second transfer gate TG2 101 forms the less sensitive path. For example, the second transfer gate may have a VDS much lower than the first gate 601. The transfer of charges from the second photodiode 200 to the floating diffusion 104 over the transfer gate 101 results in a lower voltage drop than the transfer of charges form the first sensing element PPD 100 over the transfer gate 601. For example, the drop resulting from transfer of charges from the PPD 200 to FD2 104 may be proportional to the incident radiation.

An additional means can be included for discharging the charges obtained by electron multiplication. For example, an optional ‘quench’ switch 602 (with the supply at a quench voltage 603) can be added for this purpose. The additional path ‘quench’ is provided for discharging large number of charges generated due to avalanche multiplication in APD or SPAD. It is more efficient to discharge through alternate path than through reset switch.

In the exemplary embodiments of the present invention discussed with reference to FIG. 4 to FIG. 6, the paths comprise different offsets, and further comprise elements that generate high sensitive or low sensitive response in low illumination or high illumination conditions, respectively, but both paths were connected to a single photodiode or two effectively identical photodiodes. However, a similar effect can be obtained by providing two different sensing elements, one of which being capable of generating a larger voltage drop at the input of the corresponding source follower than the other one. For example, the size of the two sensing elements can be different.

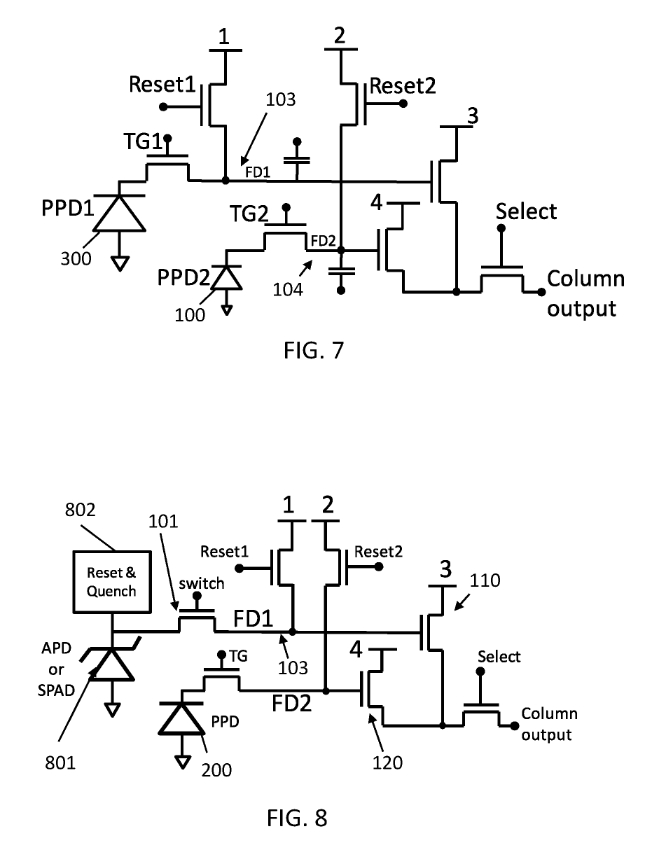

A particular embodiment of the present invention, shown in FIG. 7, comprises two subpixels, each having different sized sensing elements, e.g. photodiodes 100, 300. The sensitivity may be proportional to the difference of area between the first photodiode 100 and the larger photodiode 300, in case the capacitance values of the floating diffusion nodes 103, 104 are the same. For example, the paths may comprise connections to capacitors with the same capacitance. The larger sensing element 300 is part of the high sensitive path whereas the smaller sensing element 100 is part of the low sensitive path. Additional advantages of such embodiments include an increased area of integration, thus improving sensing in low illumination conditions.

Up to this point, the examples show one or more sensing elements of the same type. For example, the embodiments of FIG. 1 to FIG. 7 can be readily applied to photodiodes, in particular PPDs. However, the present invention is not limited to these type of photoelectric sensing elements. Other sensing elements or combinations thereof can be used.

For example, all sensing elements, or only some of them, may be avalanche photodiodes (APD). An exemplary embodiment is shown in FIG. 8 including a PPD 200 and an APD 801. The APD 801 is connected to the input of the source follower 110 through the gate 101 (e.g. a transistor such as a pass transistor). Quenching means 802 can be connected to the APD 801, for example active quenching means. These elements are part of the high-sensitive path due to the inherent charge multiplication in APD under predetermined bias voltages as known in the art. Larger signal in the floating diffusion node 103 implies a higher input voltage in the source follower 110 connected to it. The PPD 200 provides lower input voltage to the second source follower 120, thus these elements form part of the path with lower sensitivity. As before, the source terminals of both source followers are connected together, providing a single output. The output will be the one of the low sensitivity path when the illumination is high, and when the signal drops under a threshold, the output will be the one of the high sensitivity path comprising the APD 801.

In a particular example of embodiments of the present invention, the gate of one of the sensing paths (e.g. the high sensitive path) may be shaped to conform with the shape of the generated electric field, further changing (e.g. increasing) the voltage drop. For example, it may be an annular-shape gate. For example, the pixel may surround completely a transfer gate, enclosing a floating diffusion node, which may be for example in the center of a photodiode. The photodiode may be a pinned photodiode (PPD) or other type. The concentric configuration increases isolation of the floating diffusion and reduces the chances of breakdown due to the field between the trench isolation and substrate, which is advantageous for avalanche mechanisms, for example in the cases in which multiplication takes place in the MOSFET's pinch-off region.

In some embodiments, a sensing element may be allowed to transfer the charges to a highly biased floating diffusion, so the charges crossing the transfer gate (e.g. crossing and not being stored) can be multiplied. The floating diffusion for example may be the drain side of a MOSFET acting as a DC-biased transfer gate. The charges would be multiplied by hot carrier/avalanche multiplication between the pinch-off of the inversion layer and the drain (acting as floating diffusion). Insulation of floating diffusion from its surroundings (useful to avoid diode breakdown of the floating diffusion to the STI/field/substrate), can be obtained by a transfer gate completely surrounding the floating diffusion. Additionally, avalanche multiplication can be turned on and off by biasing the drain (acting as FD) high or low.

This principle can be advantageously applied to a global shutter pixel (for example including a sensing element such as a PPD, transferring charges via a first transfer gate to a storage node SN and/or a temporary storage, and to a floating diffusion via a second transfer gate).

All or part of the charge of the sensing element, e.g. PPD, is transferred to the storage node, which then either:

A) immediately proceeds via the transfer gate to the floating diffusion, with avalanche multiplication at the drain side of the gate, keeping the gate biased at a constant DC voltage, or

B) remains stored in the storage node for some time while biasing the gate low. When the transfer gate TG2 is subsequently biased higher, the charge is transferred to the floating diffusion, eventually with avalanche multiplication at the drain of the transfer gate TG2.

In a second aspect, the present invention provides a method of reading a pixel structure according to embodiments of the first aspect. The method includes reading the signal through a common output of two source followers connected to two signal paths with different gain, the two signal paths being connected to one or more sensing elements.

The method includes the step of resetting the floating diffusion nodes of each signal path (or sub-pixel) by a voltage, wherein the paths are adapted so the two paths present different offset at start of integration, before the sensing elements start generating charges due to incident radiation. The method may for example include generating an additional voltage drop in one of the paths. For example, the method may include resetting the nodes so that the nodes present different potential. However, the present invention is not limited thereto, and the reset voltage applied to each floating diffusion may be the same. If the reset voltage is the same, the source followers may have different characteristics (e.g. different threshold voltage). The output will be that of the highest voltage at reset stage for low illumination conditions. Said path may also present higher sensitivity to light. For example, if the source follower is an N-mosfet, the source of shunted source followers follows the gate voltage that is the highest in Volts. The reading of the pixel is done so that the path with highest sensitivity also has the highest voltage at reset level.

At low radiation levels (or at the beginning of the integration time, in which charges start being generated), the path with highest offset will dominate the general pixel output as the shunted source followers give an output following the source follower with highest drop between input and output. If the integrated charges surpass a predetermined point (e.g. the integrated signal passes a predetermined point), the signal through the second, low sensitive, path takes over the output. For example, at a given radiation level which is considered intense illumination, e.g. after a given time of illumination wherein charges are generated in the sensing element, charges are read in the output through the path providing lower sensitivity and higher speed.

Transfer gates in the low-sensitivity path and transfer gates in the high-sensitivity path may be simultaneously biased to allow charge transfer. Alternatively, the transfer gates may allow the transfer of charges up to a first level of the sensing element to a first floating diffusion to obtain a fast, low-sensitive readout (in which the low-sensitive path dominates the single output), and then a transfer of the remaining charges to a second floating diffusion node to obtain a high sensitive readout (in which the high sensitive path dominates the single output).

The pixel structure may undergo only two-pass readout: “reset” readout and “signal” readout. The signals at the output of both source followers are read out simultaneously, for example by directly or indirectly shunting the sources of both source followers on a reading column bus. At a particular radiation level, the signal of the high sensitivity sub pixels has dropped faster than the signal of the other sub pixel or sub pixels, and reaches the level of the sub pixel with lower sensitivity. Beyond that radiation level, the signal on the low sensitivity subpixel will dominate the overall pixel output.

The present method allows the pixel structure to advantageously undergo only two readout stages, a RESET readout and a signal readout, even in embodiments in which two different, physically separated, sensing elements are used.

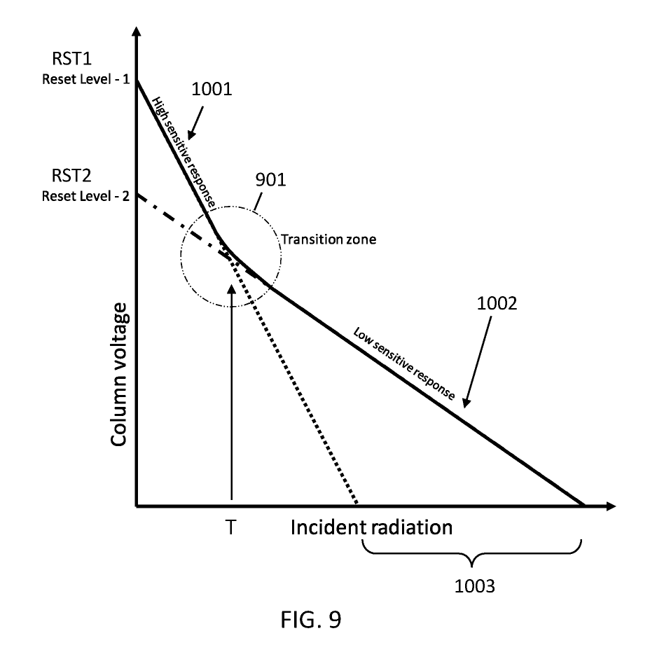

Simulations have been obtained for the readout voltage, showing the readout voltage as a function of the incident radiation (FIG. 9).

FIG. 9 shows a graph of the response at readout (column voltage) with respect to the incident radiation, showing the transition zone 901. The transition zone 901 is the environment of the crossing between the column voltage of a first source follower which at the start of the integration process for integrating incident radiation was at a first reset level RST1 (in the high sensitive path) and the column voltage of a second source follower which at the start of the integration process was at a second reset level RST2, lower than the first reset level RST1 (in the low sensitive path).

The pixel structure according to embodiments of the present invention is configured and driven such that hit highest value at the output of the first and second source followers is effectively output to a readout circuit. As illustrated in FIG. 9, at first, for low levels of incident radiation, the amount of charges transferred is low, and the path of the high sensitive response 1001 (the one including the highest voltage drop at the floating diffusion, in this case a high reset level RST1) takes over the readout. The signal starts dropping from the first reset level RST1 as the incident radiation increases. At a predetermined radiation level T, in the transition zone 901, the low sensitive response 1002 takes over. As can be seen, the range 1003 of detectable incident radiation levels is increased with respect to having the high sensitive response only, and the maximum level of incident radiation can thus be increased while still displaying a high resolution.

Calibration can be applied to the pixel structure according to embodiments of the present invention, to compensate for variability between transistors.

Calibration can be performed off-chip, so the controllers and readout do not need to be implemented in the same device, thus obtaining a compact device.

For example, each source follower may be calibrated. For example, the threshold voltage mismatch of a source follower with low sensitive output, e.g. the source follower connected to a capacitor 106 (FIG. 2), can be calibrated by dark frame subtraction, or by CDS, depending on the source follower to be calibrated. An advantage is that offsets stemming from manufacturing variability, introduced during production of the transistors and other electronic elements, can be removed, so small variations of doping levels or defects of transistors do not have a big impact in the readout. The illumination level T of the transition zone, at which the readout behavior changes from high sensitiveness to low sensitiveness, can be accurately determined.

The calibration may include the steps of defining a worst case voltage range of the transition point in the zone 901, where transition from the high sensitivity response (low gain) to the low sensitivity response (high gain) occurs. Few reference points in the high gain pixel response curve and the low gain pixel response curve may be obtained, for defining a slope. Once the high gain and low gain pixel responses are defined, the calibration may comprise

obtaining a dark image with the source follower with low gain (in the high-sensitivity path), determining a delta offset with respect to a reference, and subtracting it from the voltage in the low gain region, and

performing CDS in the high gain region to remove any offset errors in source followers connected to floating diffusions.

The outputs can then be extrapolated for the whole worst case voltage range.

1. A pixel structure comprising at least one radiation-sensing element, for generating charges when exposed to radiation, the pixel structure comprising:
a first connection arrangement between the at least one radiation-sensing element and a first source follower, the first connection arrangement comprising a switchable connection to a first reset voltage,
at least one second connection arrangement between the at least one radiation-sensing element and at least one second source follower, the second connection arrangement comprising a switchable connection to a second reset voltage,
the first and at least one second source followers having a common output,
wherein the first and second connection arrangements and source followers are configured to provide each a different offset to the common output.

2. The pixel structure according to claim 1, wherein the first and at least one second connection arrangements present different sensitivity.

3. The pixel structure according to claim 1, wherein the first and at least one second source followers comprise transistors having different threshold voltages.

4. The pixel structure according to claim 1, wherein each of the first and at least one second connection arrangements comprise a connection to a first and at least one second power supply, respectively, for resetting a starting voltage of the first and at least one second source follower via respective switches, wherein the first and at least one second power supplies provide different voltages to the respective connection arrangements.

5. The pixel structure according to claim 1, wherein the first connection arrangement and second connection arrangements each comprise a floating diffusion node, and a transfer gate, the transfer gate being for transferring charges from an associated radiation-sensing element to the floating diffusion node of that connection arrangement, wherein each connection arrangement is configured to provide a different voltage at its floating diffusion node under a same amount of charges on the associated radiation-sensing element.

6. The pixel structure according to claim 5, wherein the transfer gate of at least one of the first or second connection arrangements is a multi-level transfer gate adapted to be biased to a first bias voltage for allowing passage of charges to the floating diffusion, a second bias voltage for stopping flow of charges and to an intermediate bias voltage for allowing passage of overflown charges to the floating diffusion.

7. The pixel structure according to claim 5, further comprising a merge switch between the floating diffusion node of the first connection arrangement, and the floating diffusion node of one of the second connection arrangements.

8. The pixel structure according to claim 1, wherein at least one of the connection arrangements between the at least one sensing element and one of the first and second source followers further comprises an external capacitor.

9. The pixel structure according to claim 1, wherein the common output of the source followers is connectable to a column output via a select switch.

10. The pixel structure according to claim 1, wherein the at least one light-sensing element is a single light-sensing element.

11. The pixel structure according to claim 1, wherein the at least one light-sensing element comprises a plurality of light-sensing elements, the first and at least one second connection arrangements each connecting one of the plurality of sensing elements to a respective one of the first and at least one second source followers.

12. The pixel structure according to claim 11, wherein the plurality of light-sensing elements comprises any combination of PDs, PPDs, APDs, and SPADs.

13. A method for reading out at least one radiation-sensing element, the method comprising:
integrating electric charges generated by the at least one radiation-sensing element as a response to impinging radiation,
transferring generated charges from the at least one radiation-sensing element to a first source follower via a first connection arrangement comprising said first source follower,
overflowing generated charges from the at least one radiation-sensing element to a least one second source follower via at least one second connection arrangement comprising said at least one second source follower,
wherein the first and at least one second connection arrangements and source followers are configured to provide each a different offset to a common output, and
reading, by means of the first and second source followers, via the common output, an output value indicative of the amount of transferred charges.

14. The method according to claim 13, wherein transferring generated charges to the first and at least one second source follower is done sequentially or simultaneously.

15. The method according to claim 13, wherein transferring generated charges comprises:
transferring generated charges to a storage node in electric contact with the first source follower via a first transfer gate, the first transfer gate being adapted to transfer charges to a floating diffusion node connected to an input of the first source follower,
transferring generated charges to at least a second storage node in electric contact with the least one second source follower via at least one second transfer gate, the at least one second transfer gate being adapted to transfer charges to at least one second floating diffusion node connected to an input of the second source follower,
wherein the first and at least one second floating diffusion nodes present a different voltage at reset level.

16. The method according to claim 13, wherein the first and at least one second source followers comprise different threshold voltages for providing different offset.
